(19) United States
(12) Patent Application Publication
(10) Pub. No.: US 2026/0320068 A1
(43) Pub. Date: Oct. 15, 2026

(54) TERMINAL, SEMICONDUCTOR DEVICE MANUFACTURING SYSTEM, AND DISPLAY METHOD

(71) Applicant: HITACHI HIGH-TECH CORPORATION, Minato-ku, Tokyo (JP)

(72) Inventors: Luke Joseph Himbele, Tokyo (JP); Go SAITO, Tokyo (JP); Toru ARAMAKI, Tokyo (JP)

(21) Appl. No.: 19/099,582

(22) PCT Filed: Dec. 8, 2023
(86) PCT No.: PCT/JP2023/043944

§ 371 Date: Jan. 29, 2025

(51) Int. Cl. G06F 16/26; G01N 21/95; G06F 16/27; H10P 74/20

(52) U.S. Cl. CPC G06F 16/26; G01N 21/9501; G06F 16/27; H10P 74/203

(57) ABSTRACT

A digital dashboard in a semiconductor device manufacturing device and a semiconductor device manufacturing system including a terminal connected to a network including at least a first database storing recipe information to be used in a semiconductor manufacturing device configured to process a sample, a second database storing an electron microscope image of the sample, and a server that allows direct or indirect communication with the first database and the second database. The terminal includes a processor configured to process a communication protocol with the network; and a user interface (hereinafter, referred to as an “UI”) configured to display information stored in the first database or the second database. The digital dashboard is displayed on the UI, the digital dashboard displaying the recipe information or the electron microscope image in response to a request input from the UI.

### TECHNICAL FIELD

The present invention relates to a terminal, a semiconductor device manufacturing system, and a display method.

### BACKGROUND ART

In the related art, data collected from a plurality of information sources using a digital dashboard as one of information analysis tools is integrated and displayed in real time, and data utilization is promoted. The digital dashboard is utilized not only for marketing or business analysis but also in the field for manufacturing.

For example, PTL 1 aims to provide a “multifunction machine group control program and a multifunction machine group control method for maintaining a multifunction machine group and optimizing the multifunction machine group by using a hand held-device such as a smartphone and a tablet”, and discloses the following contents with the multifunction machine group control program and the multifunction machine group control method.

“A multifunction machine group control program according to an embodiment is a multifunction machine group control program that is executed by a hand held-device that receives a proposal or a recommendation from a data analysis server that accumulates data of a plurality of multifunction machine groups and generates a proposal or a recommendation using a machine learning function based on the accumulated data, the control program causing the hand held-device to execute: a procedure of displaying a dashboard of a plurality of selection items on a user interface of the hand held-device, a procedure of selecting one selection item in the dashboard, a procedure of displaying the proposal or the recommendation related to the selected Selection item on the user interface, and a procedure of applying the displayed proposal or recommendation to the multifunction machine selected from the user interface.”

### CITATION LIST

### Patent Literature

PTL 1: JP2021-129295A

### SUMMARY OF INVENTION

### Technical Problem

Although PTL 1 shows the utilization of a digital dashboard in a document processing device, it does not assume the utilization of the digital dashboard in a semiconductor device manufacturing device and a semiconductor device manufacturing system.

Therefore, an object of the invention is to provide a technique capable of utilizing a digital dashboard in a semiconductor device manufacturing device and a semiconductor device manufacturing system.

### Solution to Problem

In order to solve the above problems, one representative terminal according to the invention is a terminal connected to a network including at least a first database storing recipe information to be used in a semiconductor manufacturing device configured to process a sample, a second database storing an electron microscope image of the sample, and a server that allows direct or indirect communication with the first database and the second database. The terminal includes: a processor configured to process a communication protocol with the network; and a user interface (hereinafter, referred to as an “UI”) configured to display information stored in the first database or the second database. A digital dashboard is displayed on the UI, the digital dashboard displaying the recipe information or the electron microscope image in response to a request input from the UI.

### Advantageous Effects of Invention

According to the invention, a digital dashboard can be utilized in a semiconductor device manufacturing device and a semiconductor device manufacturing system.

Problems, configurations, and effects other than those described above will be made clear by the following description of an embodiment for carrying out the invention.

### BRIEF DESCRIPTION OF DRAWINGS

FIG. 1 is a diagram showing a configuration of a semiconductor device manufacturing system using a device group including a semiconductor manufacturing device and a platform.

FIG. 2 is a block diagram showing a configuration of a user personal computer.

FIGS. 3A-3C are flowcharts showing a procedure of creating a report in the semiconductor device manufacturing system.

FIG. 4 is a diagram showing an example of recipe information input to an etching device.

FIGS. 5A and 5B are cross-sectional views of a device.

FIG. 6 is a diagram showing a microscope image display including a microscope image.

FIG. 7 is a diagram showing a foreign matter information display including information related to a foreign matter.

FIGS. 8A and 8B are diagrams showing an example of a selection list shown in an output unit of the user personal computer.

FIGS. 9A and 9B are diagrams showing an example of the selection list shown in the output unit of the user personal computer.

FIG. 10 is a diagram showing a configuration of a semiconductor device manufacturing system using a device group including a semiconductor device manufacturing device and a network.

### DESCRIPTION OF EMBODIMENTS

Hereinafter, an embodiment of the invention will be described with reference to the drawings. The invention is not limited to the embodiment. In the description of the drawings, the same portions are denoted by the same reference numerals.

When there are a plurality of components having the same or similar functions, the same reference numerals may be assigned with different subscripts. When it is not necessary to distinguish the plurality of components, the description may be made by omitting the subscripts.

In the present disclosure, a “recipe” refers to a processing program that defines procedures and control parameters of processing performed in the device.

### First Embodiment

### System Configuration

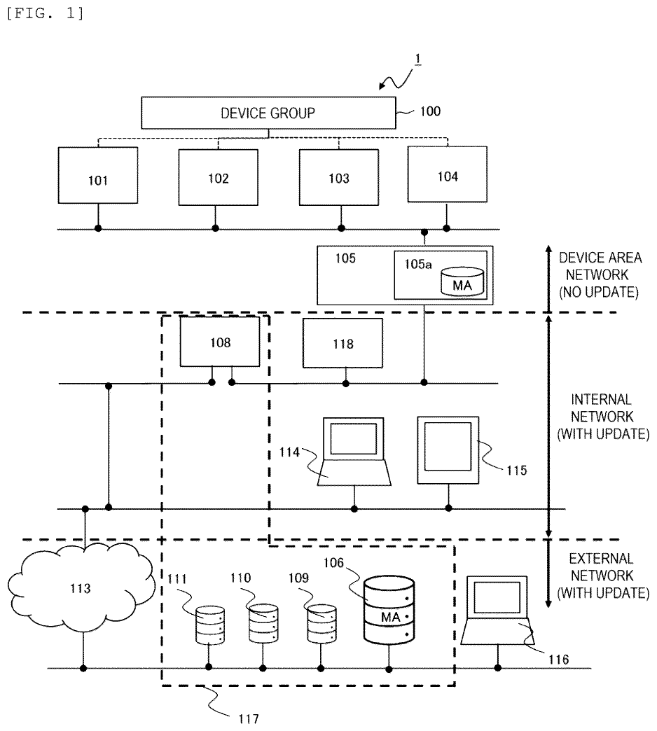

A configuration of a semiconductor device manufacturing system according to a first embodiment will be described with reference to FIG. 1. FIG. 1 is a diagram showing a configuration of a semiconductor device manufacturing system 1 using a device group including a semiconductor manufacturing device and a network 117 (hereinafter, referred to as a “platform 117”). The platform 117 is a network including a first database storing recipe information used in a semiconductor manufacturing device for processing a sample, a second database storing an electron microscope image of the sample, and a server that allows direct or indirect communication with the first database and the second database.

The semiconductor device manufacturing system 1 is capable of integrating data related to an important manufacturing device or the like in manufacturing a semiconductor device, and analyzing data for evaluating a process of manufacturing a semiconductor device, maintaining a manufacturing device, and the like. In FIG. 1, an environment to which the platform 117 is applied is classified into three areas of a device area network, an internal network, and an external network.

The device area network is a network connecting a control device for semiconductor manufacturing device (hereinafter, referred to as a “semiconductor manufacturing device PC”) 101, a control device for semiconductor inspection device (hereinafter, referred to as a “semiconductor inspection device PC”) 102, a control device for semiconductor analysis device (hereinafter, referred to as a “semiconductor analysis device PC”) 103, a control device for semiconductor analyzer (hereinafter, referred to as a “semiconductor analyzer PC”) 104, and a relay device (hereinafter, referred to as a “relay PC”) 105.

The semiconductor manufacturing device PC 101, the semiconductor inspection device PC 102, the semiconductor analysis device PC 103, and the semiconductor analyzer PC 104 are also simply referred to as “device PCs 101 to 104”. A semiconductor manufacturing device or the like controlled by the device PC is also simply referred to as a “device group 100”. The device group 100 is a collection of processing devices for processing a sample. The processing device is a device that performs processing such as manufacturing (etching), inspection, and analysis. The processing device may be referred to as a semiconductor device manufacturing device.

The internal network is a network that connects a conversion connection device (hereinafter, referred to as a “gateway PC”) 108, a user personal computer 114, a user mobile terminal personal computer 115, and a route setting device (hereinafter, referred to as a “route setting PC”) 118.

The external network is a network that connects the database server 106, an application server 109, a WEB server 110, a GPU server 111, and a remote monitor personal computer 116. The internal network and the external network are connected to each other via an Internet 113. The database server 106, the application server 109, the WEB server 110, and the GPU server 111 are also simply referred to as “server groups 106 and 109 to 111”.

The platform 117 includes the application server 109, the GPU server 111, and the WEB server 110. The application server 109 or the GPU server 111 is connected to the WEB server 110 via a communication unit. The platform 117 enables a remote access to the device PCs 101 to 104 in the device area network from the user personal computer 114 and the user mobile terminal personal computer 115 in the internal network or the remote monitor personal computer 116 in the external network. The platform 117 includes a network including the device group 100 including a semiconductor manufacturing device, the relay PC 105 that performs a security check, the gateway PC 108 having a data acquisition program, the route setting PC 118, and various databases.

The configuration of the platform 117 is an example, and is not limited to the configuration. For example, the platform may include the application server 109 and the GPU server 111, and data output from each of the device groups 100 may be downloaded by the application server 109 or the GPU server 111, as described below.

### Classification According to Security Measures

The device area network, the internal network, and the external network have different security measures for each area.

The device area network is a network to which at least a semiconductor manufacturing device is connected. The device area network is, for example, a network implemented by a manufacturing device or the like constituting a production line in a semiconductor manufacturing factory. The device area network may include, for example, a network such as a device that automatically transports a member and a finished product, and a device that automatically stores and retrieves a member.

The internal network is, for example, a network to which a server or the like that performs production management is connected. In addition to the management of a production plan, for example, a server for monitoring a production status and acquiring facility information is connected to the internal network. A server that performs information collection for receiving an order of a member and formulating a production plan may be connected. The internal network may include, for example, a management department of a head office.

The external network is a network connected to the device area network and the internal network via the Internet. The external network is a network that is not managed by a semiconductor manufacturing factory or a head office, and may be connected for remote maintenance by a device vendor, for example.

Next, security measures will be described. The security measures such as preventing intrusions into a communications network, preventing unauthorized intrusions into the area, account management, monitoring of communication logs and operation logs, and monitoring alerts for PCs and terminals are set up for each of the three areas. For example, the device area network includes a network made up of devices within a semiconductor manufacturing factory, and as the security measures, measures are taken to prevent unauthorized intrusion into the premises, and to restrict the use of terminal devices such as PCs.

Here, for example, attention is paid to update of software (in particular, update of an OS) among the security measures. In this case, updating the OS is expected to eliminate vulnerability and prevent an unauthorized access from outside. Although the OS is updated in the internal network and the external network, there is a case in which a device or an equipment whose OS is not updated exists in the device area network.

### Configuration for Each Area

In the first embodiment, an etching device is described as an example of the processing device. The etching device can also be referred to as a semiconductor manufacturing device that processes a semiconductor wafer (hereinafter, also simply referred to as a “wafer”) as a sample. The present disclosure is not limited to the etching device, and may be applied to other processing devices. In the following description, a case of a semiconductor wafer will be described. The present disclosure may also be applied to samples other than the semiconductor wafer.

### Device Area Network

The semiconductor manufacturing device PC 101 is a device that manages control of, for example, a wet etching device and a plasma etching device (hereinafter, also simply referred to as an “etching device”). The semiconductor inspection device PC 102 is a device that controls a visual inspection device such as a camera or a microscope and an electric inspection device using a probe. The semiconductor analysis device PC 103 is a device that controls an analysis device such as a transmission electron microscope or an atomic force microscope. For example, the semiconductor analyzer PC 104 is a device that controls an analyzer that performs TCT gas chromatograph/mass spectrometry and time-of-flight secondary ion mass spectrometry. The semiconductor analyzer PC 104 can also control a foreign matter measuring instrument such as a laser measuring device for measuring a foreign matter on an etched wafer. Although the control device is classified for each function of inspection, and analysis, the classification is not limited thereto. A plurality of functions may be implemented by one control device, or may be appropriately set based on a manufacturing process performed in the semiconductor device manufacturing system 1 to which the platform 117 is applied.

When a processing recipe for performing the etching processing is input to the semiconductor manufacturing device PC 101, the semiconductor manufacturing device PC 101 executes the processing recipe. An instruction value according to contents of the processing recipe in the etching device is transmitted from the semiconductor manufacturing device PC 101 to each equipment in the etching device, and the etching processing is performed in the etching device. The processing recipe thus executed is stored in the semiconductor manufacturing device PC 101.

The etched wafer is conveyed to one of the semiconductor inspection device, the semiconductor analysis device, and the semiconductor analyzer. Upon receiving the measurement recipe for inspection, the semiconductor inspection device PC 102 controls the semiconductor inspection device according to the measurement recipe. A measured result is stored in the semiconductor inspection device PC 102. Similarly, the semiconductor analysis device PC 103 receives the measurement recipe for analysis and controls the semiconductor analysis device according to the measurement recipe. A measured result is stored in the semiconductor analysis device PC 103. The semiconductor analyzer PC 104 receives a measurement recipe for analysis and controls the semiconductor analyzer according to the measurement recipe. A measured result is stored in the semiconductor analyzer PC 104.

According to the device group 100 and the device PCs 101 to 104, for example, it is possible to acquire data related to a state (for example, a pressure, a temperature, a foreign matter number, a gas type, or a plasma density) in the etching device during the etching processing. A microscope image of the etched wafer and data associated with a result of length measurement performed on the microscope image are obtained. In addition, data related to the foreign matter number on a wafer measured by the foreign matter measuring instrument after the etching is obtained.

### Data Communication between Areas

The first embodiment will be described again with reference to FIG. 1. In a device area network in which the device group 100 including the semiconductor manufacturing device such as the etching device is provided, the relay PC 105 is provided which is network-connected to each device of the device group 100. The relay PC 105 has a unit for communicating data in two directions between the control device of each device of the device group 100 and the relay PC 105, and has a program for performing a security check on data and a storage unit for storing data that passes the security check. Specifically, the relay PC 105 includes a communication unit such that the relay PC 105 can collect data obtained from the device group 100 or the device PCs 101 to 104. The relay PC 105 has a storage unit in which data indicating a result received from the device group 100, master data to be described later, and the like are stored and an access right is limited to only the relay PC 105. For example, a folder in which a result of each device group is stored using server message block (SMB) communication, which is a communication protocol, is created as a shared folder 105a, and the access right is given to the relay PC 105. Accordingly, the relay PC 105 can collect output data output from each device of the device group 100. The relay PC 105 can also transfer (transmit) data to the device group 100. For example, the relay PC 105 receives the recipe from the gateway PC 108 and inputs the recipe to each device of the device group 100. Although the shared folder 105a is illustrated in the above description, the form of the storage unit is not limited thereto. As the storage unit, a storage device within the relay PC 105 may be used, or an external storage device such as a hard disk that is separate from the relay PC 105 and can be connected to the relay PC 105 may be used.

The relay PC 105 is implemented to be able to update the OS via the external network. The relay PC 105 also has a built-in program for performing the security check on data, such as virus software, and is capable of executing the program, so that a latest virus definition is always reflected. A constant security monitoring destination in the virus software is set to the shared folder 105a, and data stored in the shared folder is constantly subjected to the security check. Only the shared folder can be accessed from the internal network and the external network, and is also used as a storage location of data such as a recipe transferred to the device group 100.

The shared folder 105a manages a device master MA that includes at least a device ID assigned to each device in the device group 100. The device master MA is also stored in the database server 106 in the external network.

Although one shared folder is illustrated, a plurality of shared folders may be provided. For example, the shared folder is created between the relay PC 105 and the device PCs 101 to 104 by using, for example, an SMB protocol as a folder in which data to be taken out and utilized from the external network is stored in the device PCs 101 to 104.

The device master MA is stored in the database server 106, and may also be stored in another server included in the external network.

### Internal Network

The internal network is formed outside the relay PC 105. The gateway PC 108 is provided in the internal network. The gateway PC 108 has a built-in program and executes a program for accessing the device master MA based on authentication information of the external network or authentication information of the platform 117, and for acquiring output data allowed by the device master MA from a storage unit. Specifically, the gateway PC 108 can access the shared folder 105a via the relay PC 105, and can collect the output data from the device group 100 by referring to the device master MA.

The route setting PC 118 has a built-in program that allows the gateway PC 108 to access the storage unit and transfer the output data obtained therefrom to the internal network, or the output data stored in the storage unit to the device group 100, and blocks spontaneous data leakage from each device in the device group 100.

Accordingly, the gateway PC 108 can access the storage unit of the relay PC 105, but prohibits transferring data from the device area network side to the internal network.

The user personal computer 114 and the user mobile terminal personal computer 115 are operated by a user who uses the platform 117. The semiconductor device manufacturing system 1 is connected to the platform 117, the user personal computer 114, and the user mobile terminal personal computer 115 via a communication unit.

### External Network

The database server 106 stores the device master MA and the user authentication information. The database server 106 stores the output data (for example, data indicating the result acquired by the device group 100, manufacturing data output from each device of the device group 100, and a microscope image acquired by the microscope device included in the device group 100) output from each device of the device group. The database server 106 may include a plurality of database servers, and includes, for example, at least a first database storing recipe information to be used in a semiconductor manufacturing device for processing a sample and a second database storing an electron microscope image of a semiconductor wafer.

The application server 109 receives a user request transferred from the WEB server 110, executes the application program, and responds to the WEB server 110. When it is necessary to search and update data, the application server 109 requests the database server 106 to process data, and, after processing the data, responds to the WEB server 110 with a dynamic content. The application server 109 is a server capable of communicating directly or indirectly with the first database and the second database. The direct or indirect communication is a communication in which wired or wireless communication mode or a communication protocol may be selected appropriately. The application server 109 also has an editing function for creating a report based on a display of a digital dashboard.

In response to the user request, the WEB server 110 responds with a static Web content (an HTML page, a file, an image, a video, and the like), or when dynamic processing is necessary, it requests the application server 109 to perform the processing and receives a dynamic content response from the application server 109.

The database server 106 performs the processing according to a request from the application server 109, and transfers a result to the application server 109.

The GPU server 111 generates a content on behalf of the application server 109 when the user request involves a heavy load.

### Configuration for Acquiring Data Utilized in Digital Dashboard

In the present disclosure, the WEB server 110 shares a digital dashboard with the user personal computer 114. The application server 109 stores the application programs required when creating the digital dashboard and executes a calculation logic in these application programs. The database server 106 acquires manufacturing environment data acquired for each recipe, data such as characteristics of a device, and the like. Hereinafter, details will be described.

The database server 106 functions as a data warehouse (DWH) and integrally accumulates data to be utilized in the digital dashboard. The application server 109 processes data acquired from the processing device, the first database, and the second database based on a template to be used in the digital dashboard. Specifically, the application server 109 includes an extract, transform, load (ETL) tool, and extracts, converts, and writes the data to be utilized in the digital dashboard in the database server 106. The data stored in the database server 106 includes, for example, the recipe information related to a recipe for performing the etching processing, the state in an etching device during the etching processing, the foreign matter number in a wafer during the etching processing, a microscope image of the wafer after the etching processing, and length measurement data. The application server 109 includes a VER application for calculating an etch rate, and can calculate the etch rate based on the length measurement data acquired over time. The data is organized in time series in the database server 106, and new data is accumulated as needed. Since the data is arranged in a multidimensional array along axes such as a “time,” an “environmental condition”, and a “recipe”, it is possible to analyze a change in the recipe and a tendency (trend) in a certain period in the processing process, or to perform factor analysis when a change occurs. A combination of the data and a visualization method can be set in advance, and the user can select a combination of data and a display mode from the template.

In general, it is assumed that a provider of a service of the digital dashboard is different from an administrator of the device area network and the internal network. From the viewpoint of the security measures and the like, there is a case in which the provider of the service of the digital dashboard is required to be limited more than necessary to handle data in the device area network and the internal network. In the present disclosure, since the database server 106, the application server 109, and the WEB server 110 are provided in the external network, even when the provider of the service of the digital dashboard is provided, it is possible to perform data processing without being limited in terms of the security measures, and it is also advantageous in terms of a service operation such as facility improvement and maintenance.

Although the embodiment will be described with reference to the database server 106, the application server 109, and the WEB server 110, the present disclosure is not limited to this case. For example, a combination of an application server and a database server may be set for each application program. Although a server configuration including the web server 110, the application server 109, and the database server 106 will be described, the present disclosure is not limited to this case, and may be, for example, a configuration including a front-end server and a back-end server. The server is not limited to the hardware configuration, and may be provided by cloud services.

### Configuration of Terminal

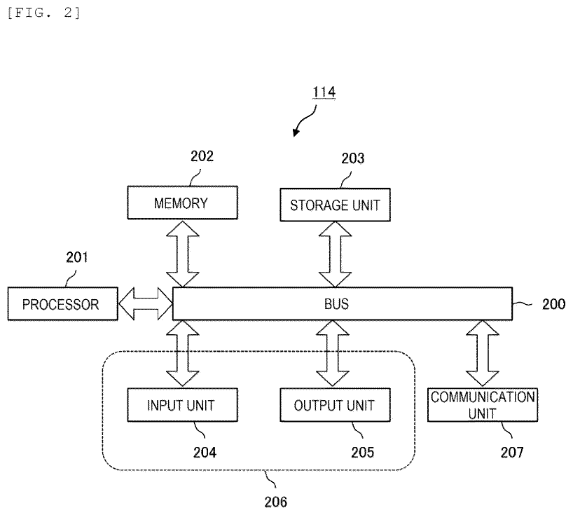

An example of a configuration of the user personal computer 114 will be described with reference to FIG. 2. FIG. 2 is a block diagram showing the configuration of the user personal computer 114. The user personal computer 114 (hereinafter, also referred to as a “terminal”) is connected to the platform 117, and includes a processor that processes a communication protocol with the platform 117, and a user interface (hereinafter, referred to as a “UI”) that displays information stored in the first database and the second database, and a digital dashboard that displays the recipe information or the electron microscope image in response to a request input from the UI is displayed on the UI. Hereinafter, details will be described.

The user personal computer 114 includes a processor 201, a memory 202, a storage unit 203, an input unit 204, an output unit 205, and a communication unit 207, each of which is connected to the processor 201 via a bus 200.

The processor 201 controls each configuration of the user personal computer 114. The processor 201 is, for example, a central processing unit (CPU), a digital signal processor (DSP), a graphics processing unit (GPU), or a field-programmable gate array (FPGA). The processor 201 performs processing for enabling the user personal computer 114 to function, and for example, processes a communication protocol with the platform 117 in regard to communication.

The memory 202 stores a program for achieving various functions by being executed by the processor 201. The memory 202 includes, for example, a read only memory (ROM) and a random access memory (RAM).

The storage unit 203 stores data processed by the processor 201, data input from the input unit 204, and the like. The storage unit 203 is a hard disk drive (HDD) or a solid state drive (SSD).

The input unit 204 receives a user request or processed data into the user personal computer 114. The input unit 204 is a mouse, a keyboard, or the like.

The output unit 205 outputs to the user the result processed by the processor 201. The output unit 205 is, for example, a liquid crystal display or an organic electro-luminescence (EL) display.

Since the input unit 204 and the output unit 205 share a function of mediating between the user personal computer 114 and the user, the input unit 204 and the output unit 205 are collectively referred to as the interface (UI). As will be described later, the digital dashboard which displays the recipe information and the electron microscope image is displayed on the UI (in particular, the output unit 205) according to the request input from the UI (in particular, the input unit 204).

The communication unit 207 transmits and receives data to and from other devices via a network. The communication unit 207 is, for example, a network interface card (NIC), a wireless communication module, a universal serial Interface (USB) module, or a serial communication module.

The above description shows an example of the configuration of the user personal computer 114, and the invention is not limited to the example.

The user mobile terminal personal computer 115 includes a touch panel display in which the input unit 204 and the output unit 205 are integrated with each other in the above-described user personal computer 114. As for other configurations, the user mobile terminal personal computer 115 and the user personal computer 114 have the same configuration. The remote monitor personal computer 116 has the same configuration as that of the user personal computer 114. In the following description, the case in which the user personal computer 114 is used will be described. The present disclosure can also be applied to a case in which the user mobile terminal personal computer 115 and the remote monitor personal computer 116 are used. However, an operation method and a display mode of the digital dashboard may not necessarily be common among the user personal computer 114, the user mobile terminal personal computer 115, and the remote monitor personal computer 116. Depending on the configuration of the personal computer or a difference in user authentication, the operation method and the display mode may be changed.

In the following description, a case will be described in which the digital dashboard generated mainly in the application server 109 of the platform 117 is displayed on the output unit 205 of the user personal computer 114, and the present disclosure is not limited to this case. For example, in the user personal computer 114, an application program for creating a digital dashboard according to execution of the processor 201 may be stored in the memory 202.

### Operation Method

When using the semiconductor device manufacturing system 1, the user registers the authentication information in order to log in from the user personal computer 114 to the platform 117. The authentication information of the user is stored in the database server 106. When the authentication information of the user, such as a user ID and a password, is entered from the user personal computer 114, the authentication information is compared with the authentication information stored in the database server 106 to authenticate the user. When the log in is to be performed in the platform 117, the authentication information of the user is also applied to the database server 106, the application server 109, the WEB server 110, and the GPU server 111.

### Flowchart of Control

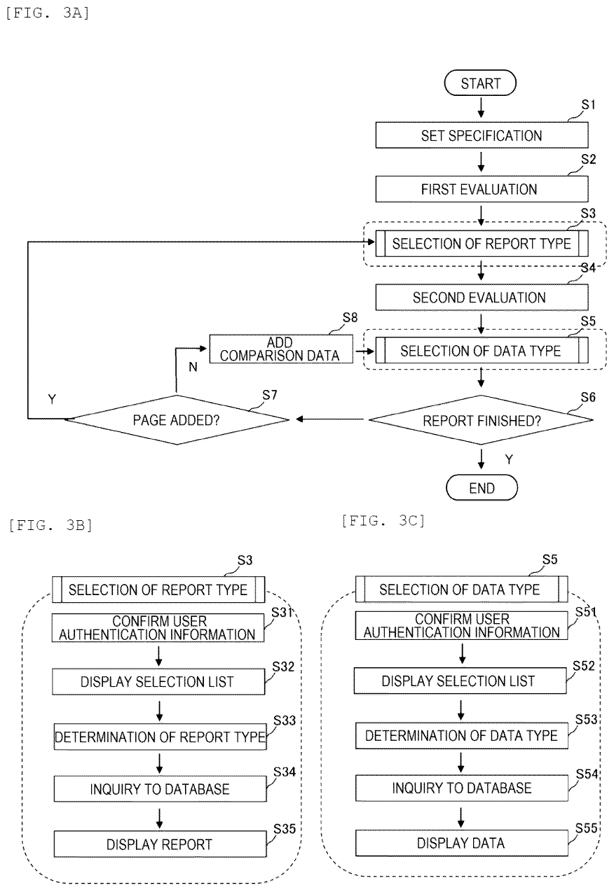

Processing in which report creation is performed will be described with reference to FIGS. 3A-3C. A report is obtained by aggregating information such as an index, a device state, and the like monitored at a manufacturing stage, and is created when specifications of the device manufactured using the device group 100 are satisfied. In the present disclosure, it is possible to confirm a state of the device group 100 and a state of the semiconductor wafer at the manufacturing stage by using a digital dashboard, and it is possible to manufacture devices so that the devices meet the specifications while performing various kinds of control such as Run to Run control.

FIGS. 3A-3C are flowcharts showing a procedure of creating a report in the semiconductor device manufacturing system 1. FIG. 3A shows processing performed based on a user request input from the user personal computer 114, and (FIG. 3B and FIG. 3C mainly show processing performed in the application server 109 included in the platform 117.

First, processing performed based on the user request input from the user personal computer 114 will be mainly described with reference to FIG. 3A.

First, in step S1, a Specification is set. The specification indicates a structure and characteristics of a device to be implemented by the processing performed in the device group 100. For example, when the processing performed by the etching device in the device group 100 is performed, the specification is a shape of a device such as a physical width, an etching rate, and a width depth in a device formed on a wafer. The specification can also be referred to as a pattern shape after etching, a target of etching, and dimensions after etching. The specification is not limited to a numerical value that defines the structure physically, and includes processing conditions in the manufacturing device and electrical characteristics of the device. In the case of the etching device, the specification is input to the semiconductor device manufacturing system 1 via the input unit 204 of c the user personal computer 114. The device group 100 performs processing of a semiconductor wafer based on the specification and a recipe set based on the specification.

Subsequently, in step S2, first evaluation is performed. The first evaluation is first evaluation performed on the wafer after the processing is performed in the device group 100. The first evaluation is evaluation before a digital dashboard and a report to be described later are created.

Subsequently, in step S3, a report type (display mode) is selected. The selection of the report type refers to the selection of the display mode of the information to be posted in the report. For example, when an abnormality in particles (foreign matter) is confirmed at the time of the first evaluation in step S2, a display mode suitable for particle analysis (for example, a line graph of the foreign matter number in a manufacturing process) is selected. The report type will be described later.

Subsequently, in step S4, second evaluation is performed. The digital dashboard is created according to the report type selected in step S3. At the time of the second evaluation, data analysis utilizing the digital dashboard and the specification is performed. The user can perform the data analysis while confirming the digital dashboard indicated by the output unit 205 of the user personal computer 114.

Subsequently, in step S5, a data type is selected. For example, in addition to the particles that are the focus of attention in the first evaluation, the etching rate may also need to be analyzed in the second evaluation. In such a case, the etching rate is selected as data to be posted on the digital dashboard in addition to particles. At the stage of the second evaluation, in addition to the data obtained at the stage of the first evaluation, information related to environmental conditions in which the processing is performed, such as a pressure and a temperature in a chamber in the case of the etching device, and analysis information on a microscope image or the like which is related to the device after processing, are also collected. The data type can be selected from the data related to the information.

Subsequently, in step S6, it is determined whether the report is finished. The report is created when the result that Satisfies the specification is obtained in the semiconductor device manufacturing system 1, and thus when it is confirmed in the digital dashboard or the acquired data that the specification is satisfied, the report is created (Y (Yes) in step S6).

On the other hand, when it is not confirmed that the specification is satisfied (N (No) in step S6), in step S7, it is determined whether to add a page of the report. The additional page describes information related to additional processing. When a page is added (Y in step S7), the processing returns to step S3, and a report related to the additional processing performed by the device group 100 is created. The processing is performed by the device group 100 again so as to satisfy the specification.

Further, when a page is not added (N in step S7), comparison data is added (step S8). When the addition of the comparison data is selected, the processing returns to step S5 and the data obtained in the course of another processing is referred to based on the data acquired by the current processing. Thereafter, a temporary report may be created (Y in step S6), and the procedure may be repeated until the specification is satisfied.

The application server 109 has a function of storing the created report, reading and searching for the stored report. The application server 109 has a function of storing a report with a document number (TS-No) attached thereto and searching for a report using the stored TS-No as an ID. The report created by the application server 109 is stored, for example, by assigning the TS-No to the database server 106. When the report is searched from the user personal computer 114, the report is searched based on the TS-No and displayed on the output unit 205 of the user personal computer 114.

### Selection of Report Type

The selection of the report type in step S3 will be described with reference to FIG. 3B. First, in step S31, the user authentication information is confirmed. Regarding the confirmation of the user authentication information, in step S31, the user is prompted to input the authentication information via the input unit 204 of the user personal computer 114. The application server 109 performs comparison with the authentication information stored in the database server 106. In addition, the user ID and the password input when the user logs in the platform 117 may be used in the application server 109.

Subsequently, in step S32, a selection list is displayed. The WEB server 110 displays the selection list on the output unit 205 of the user personal computer 114. In the selection list, a display mode (template) of a report to be displayed on the digital dashboard is posted. The display mode of the report includes, for example, a microscope report indicating information related to a microscope image, a foreign matter number in the etching device, and a particle (PA) report including foreign matter information such as a foreign matter on the wafer.

Subsequently, in step S33, the report type is determined. When the user selection is received by the input unit 204 of the user personal computer 114, the WEB server 110 receives the user selection.

Subsequently, in step S34, an inquiry to the database is performed. The WEB server 110 inquires of the database server 106 about a report corresponding to the determined report type.

Subsequently, in step S35, the report is displayed. The WEB server 110 displays the selected report type on the output unit 205 of the user personal computer 114.

The processing of step S31 is performed to store the user and the result of the selection of the report type performed by the user in association with each other. When a report identical to the finished report is to be created, the report type can be efficiently selected by referring to the user and the information on the selection of the report type.

### Selection of Data Type

The selection of the data type in step S5 will be described with reference to FIG. 3C. First, in step S51, the user authentication information is confirmed. The processing of confirming the authentication information of the user is the same as that of step S31. When an expiration date is provided in the authentication information, the processing of step S51 can be omitted when the expiration date of step S31 is continued at the time of step S51.

Subsequently, in step S52, a selection list is displayed. The WEB server 110 displays a selection list on the output unit 205 of the user personal computer 114. In the selection list, data types to be used in the report are posted. The data type includes, for example, data acquired by processing for each wafer or batch, a state of a processing chamber (for example, a vacuum degree, a temperature, or a plasma generation state in the case of a plasma device), and coordinates captured in the case of microscope image data.

Subsequently, in step S53, the data type is determined. When the user selection is received by the input unit 204 of the user personal computer 114, the WEB server 110 receives the user selection.

Subsequently, in step S54, an inquiry to the database is performed. The WEB server 110 inquires of the database server 106 about the selected data type.

Subsequently, in step S35, the data is displayed. The WEB server 110 causes the output unit 205 of the user personal computer 114 to display a digital dashboard including the selected data type.

In the case of the selection of the data type, the user and the result of the selection of the data type performed by the user are stored in association with each other. This enables efficient selection of the data type for subsequent report creation.

### Recipe Information

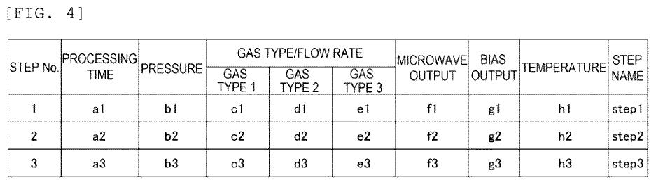

The recipe information input to the device PCs 101 to 104 will be described with reference to FIG. 4. FIG. 4 is a diagram showing an example of the recipe information input to the etching device. The recipe includes items of a “step No.” , a “processing time”, a “pressure”, a “gas type/flow rate”, a “microwave output”, a “bias output”, a “temperature”, and a “step name”.

The item “step No.” indicates a process included in plasma processing. When the plasma processing is performed in the etching device, a plasma environment generated in the etching processing device is achieved by a setting condition set for each step No. The “processing time” indicates a period during which the setting condition is maintained. The “pressure” indicates a pressure in the etching device under which a wafer is placed. The “gas type/flow rate” indicates a type and a flow rate of the gas supplied into the etching device. In the example of FIG. 4, three types of gases are used. The “microwave output” indicates an output value of a microwave applied to the etching device. The “bias output” indicates a voltage applied to the wafer. The “temperature” indicates a set temperature of a place where the wafer is arranged. The “step name” is a search key of step No. As shown in FIG. 4, a predetermined setting value is input for each item.

The recipe information is displayed on the digital dashboard in response to a user request input from the UI of the user personal computer 114. For example, as will be described later, when the content of the digital dashboard is generated by designating a Run number, the recipe information executed based on the Run number is displayed on the digital dashboard. When the content f the digital dashboard is generated by designating the state in the etching device, a driving condition of the device related to the state in the device is extracted from the recipe information and displayed on the digital dashboard.

### Specification

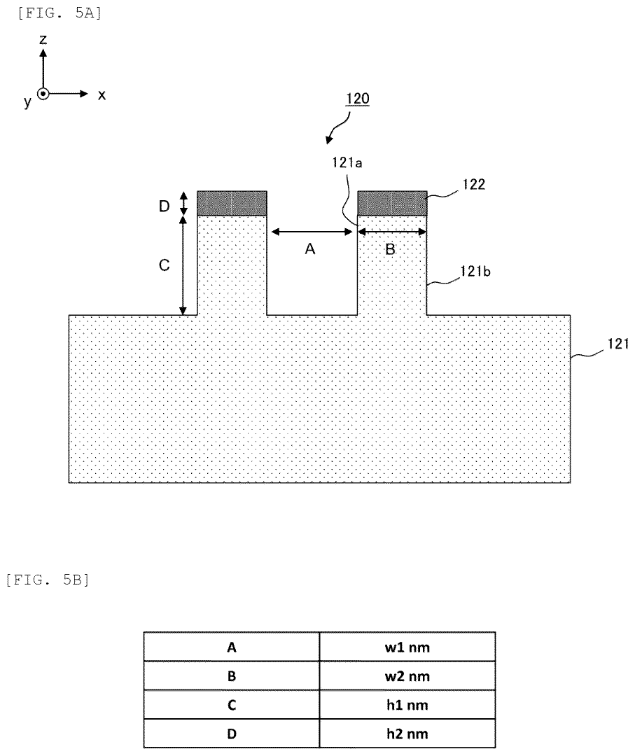

Next, the specification will be described with reference to FIGS. 5A and 5B. FIGS. 5A and 5B are cross-sectional views of the device. FIG. 5A schematically shows a case in which a device 120 is etched from a z-axis direction. A resist layer 122 having a predetermined pattern shape is formed on a wafer 121, and portions of the wafer 121 on which the resist layer 122 is not formed are etched to form trench shapes. When the trench shape is identified, a width A of a groove portion 121a of the wafer 121, a width B of a protrusion 121b of the wafer 121, a height C of the protrusion 121b, and a thickness D of the resist layer can be taken as characteristics of the trench shape. As for the specification, as shown in FIG. 5B, each of the width A to the thickness D is associated with a predetermined setting value.

### Examples of Report Type

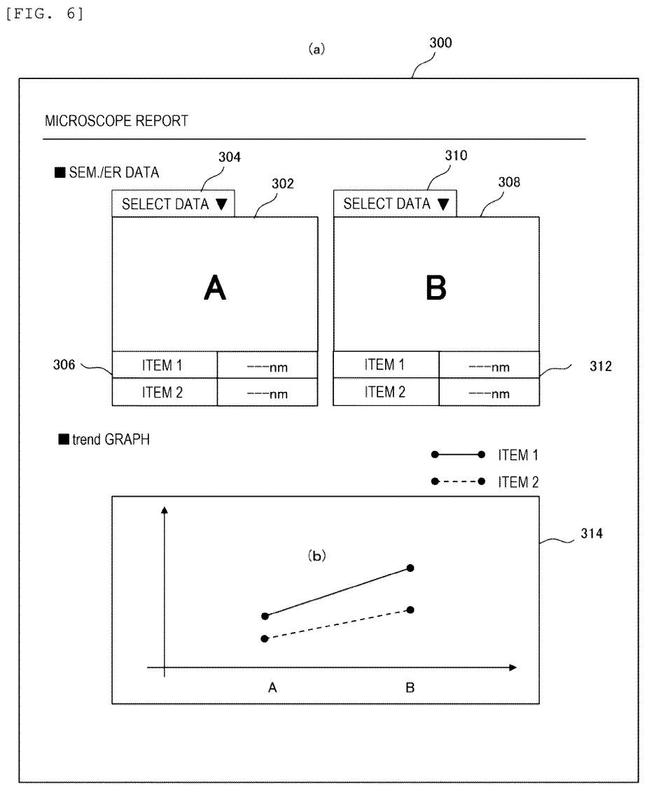

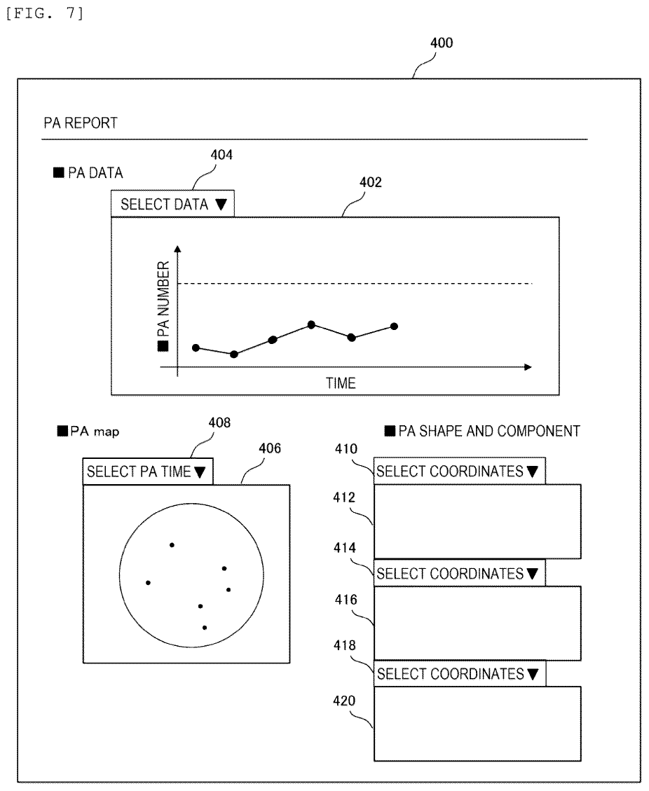

Next, an example of the report type (display mode of information posted on a report) will be described with reference to FIGS. 6 and 7. FIGS. 6 and 7 show display modes of information to be posted on a final report, and are a portion of the information displayed on the digital dashboard on the output unit 205 of the user personal computer 114 while the wafer is being processed. FIGS. 6 and 7 are display modes selected from the selection list (corresponding to the selection list in step S32 of (b) of FIG. 2) displayed on the output unit 205 of the user personal computer 114. The digital dashboard includes a microscope report including a microscope image or a particle report including foreign matter information. Hereinafter, details will be described.

FIG. 6 is a diagram showing the microscope image display including the microscope image. A microscope image display (microscope report) 300 includes microscope images (SEM/ER data) 302 and 308. The microscope image 302 corresponds to the data selected from a data selection unit 304. A length measurement table 306 show measurement values of portions defined in, for example, the specification (corresponding to step S1 in (a) of FIG. 2) for the device from which the microscope image 302 is acquired. The length measurement table 306 includes an item 1 and an item 2, and the number of items may be other than two.

The microscope image 308 is a microscope image selected as a comparison target when, for example, the comparison data is added (corresponding to step S8 in (a) of FIG. 2). The microscope image 308 corresponds to data selected from a data selection unit 310, and is associated with a length measurement table 312 in the same manner as the microscope image 302.

A comparison graph (trend graph) 314 shows values at the time of the microscope image 302 and values at the time of the microscope image 308 for the length measurement items 1 and 2.

The microscope image display 300 is set in advance as a template, and the microscope image, the length measurement table, and the comparison graph are displayed according to the data selected from the data selection unit 304 and the data selection unit 310.

Although two microscope images are included in the above description, the present disclosure is not limited thereto. For example, it is also possible to set a template including three microscope images.

FIG. 7 is a diagram showing a foreign matter information display including information related to a foreign matter. A foreign matter information display (particle (PA) report) 400 includes a foreign matter number scatter diagram (PA data) 402 indicating a temporal change in the foreign matter number and a foreign matter distribution diagram (PA map) 406 indicating a measurement result of the foreign matter on the wafer. The foreign matter number scatter diagram 402 corresponds to the data selected from a data selection unit 404. In the foreign matter number scatter diagram 402, an elapsed time of the etching processing is plotted on a horizontal axis, and the foreign matter number is plotted on a vertical axis. In the foreign matter information display 400, the information is updated every time the foreign matter number s is measured, and the measurement result is shown in real time.

The foreign matter distribution diagram 406 indicates a distribution of the foreign matter on the wafer over the elapsed time of the etching processing selected from the data selection unit 408, for example. By setting the coordinates of the foreign matter distribution diagram 406 through data selection units 410, 414, and 418, a foreign matter shape and foreign matter components in the set coordinates are displayed in display fields 412, 416, and 420, respectively.

### Example of Data Type

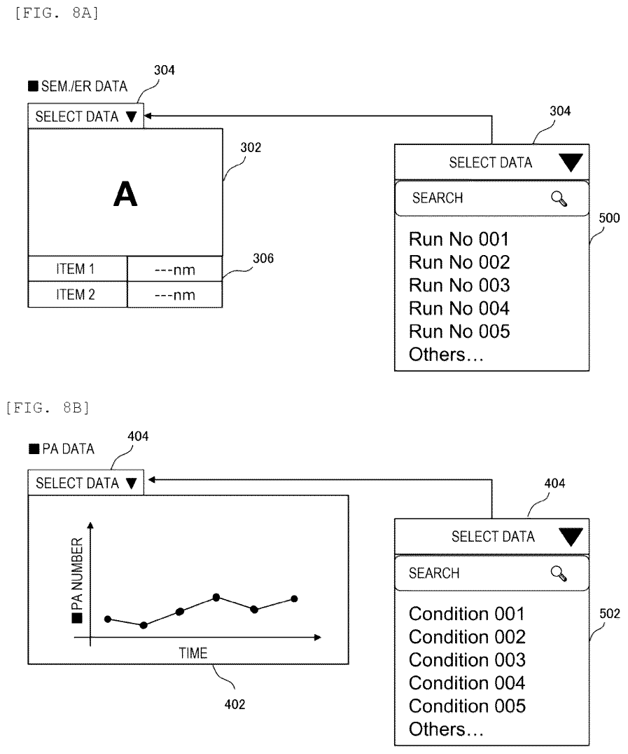

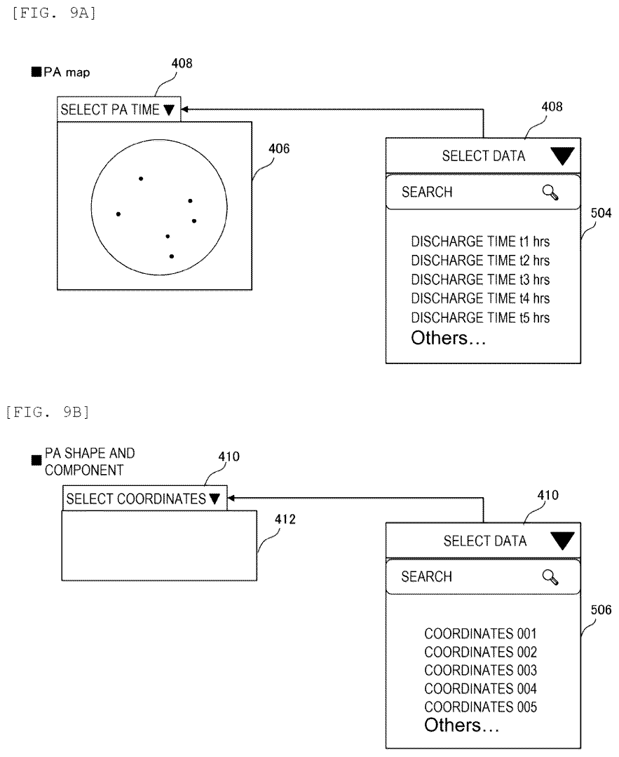

Next, an example of the data type will be described with reference to FIGS. 8A and 8B and 9A and 9B. FIGS. 8A and 8B and 9A and 9B are diagrams showing an example of the selection list displayed on the output unit 205 of the user personal computer 114. The selection list corresponds to the selection list in step S52 of (c) of FIG. 2.

FIG. 8A shows a selection list 500 to be displayed when the data selection unit 304 of the microscope image 302 is selected in the microscope image display 300. The selection list 500 includes a Run number (Run No.) 001 to a Run number 005. The Run number is an index corresponding to the processed wafer, and is a number to be added every time one wafer is processed (one time when the etching processing is performed in batch processing). The selection list 500 is displayed on the output unit 205 of the user personal computer 114, and the Run number is selected via the input unit 204 of the user personal computer 114. The application server 109 has a function of accessing data based on the Run number designated by the UI of the user personal computer 114. The application server 109 extracts a microscope image based on the Run number from the database server 106. A microscope image of the etched wafer according to the Run number selected by the user is displayed in the microscope image 302.

FIG. 8B shows a selection list 502 to be displayed when the data selection unit 404 of the foreign matter number scatter diagram 402 is selected in the foreign matter information display 400. The selection list 502 includes Condition 001 to Condition 005 in relation to a state (Condition) in the etching device. The selection list 502 is displayed on the output unit 205 of the user personal computer 114, and the state is selected via the input unit 204 of the user personal computer 114. The foreign matter number scatter diagram 402 displays the elapsed time of the etching processing during a period when a predetermined state is established as a time on a horizontal axis, and the foreign matter number in the etching processing during that period as a vertical axis.

FIG. 9A shows a selection list 504 to be displayed when the data selection unit 408 of the foreign matter distribution diagram 406 is selected in the foreign matter information display 400. The selection list 504 includes a discharge time t1 to a discharge time t5 related to a discharge time indicating an elapsed time during discharge in certain etching processing. The selection list 504 is displayed on the output unit 205 of the user personal computer 114, and the discharge time is selected via the input unit 204 of the user personal computer 114. The foreign matter distribution diagram 406 displays a distribution of the foreign matter on the wafer measured at the discharge time selected by the user.

FIG. 9B shows a selection list 506 to be displayed when the data selection unit 410 is selected in the foreign matter information display 400. The selection list 506 includes a coordinate 001 to a coordinate 005 in the foreign matter distribution diagram 406. The selection list 506 is displayed on the output unit 205 of the user personal computer 114, and coordinates are selected via the input unit 204 of the user personal computer 114. A display field 412 displays a foreign matter shape and a foreign matter component in the coordinates selected by the user.

### Functions and Effects

According to the invention, a digital dashboard can be utilized in a semiconductor device manufacturing device and a semiconductor device manufacturing system. In particular, the recipe information and the microscope image are unique information in the semiconductor device manufacturing system, and the information can be confirmed as a list with information that changes in real time. Since the report can be created through the operation of the digital dashboard using the template, a burden on the user related to the report creation is reduced, and efficiency when evaluating the semiconductor device manufacturing system can be improved.

### Second Embodiment

A second embodiment is different from the first embodiment in that data utilized in a digital dashboard is stored in a cache.

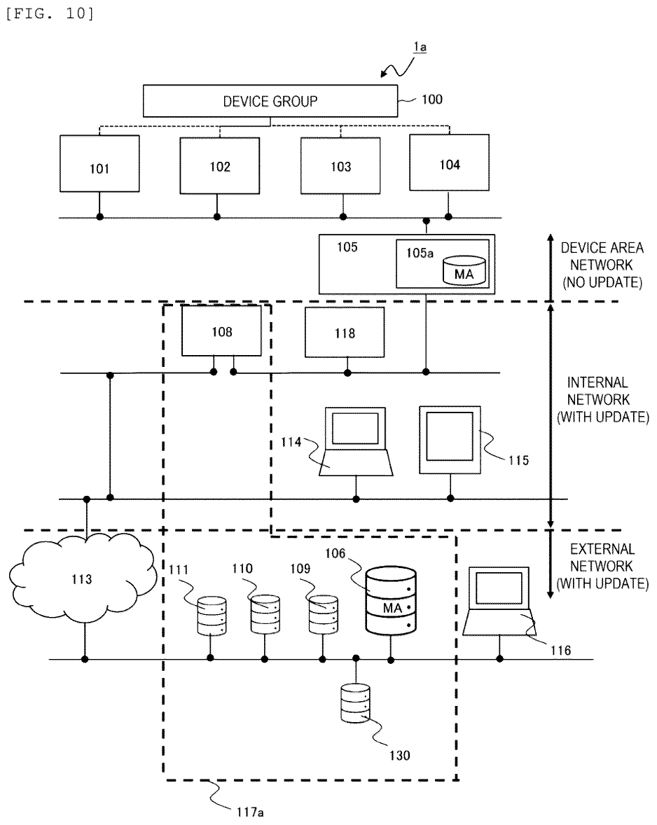

FIG. 10 is a diagram showing a configuration of a semiconductor device manufacturing system la using a device group including a semiconductor manufacturing device and a network 117a (hereinafter, referred to as a “platform 117a”). In the following description, components that are the same as or equivalent to those according to the first embodiment described above are denoted by the same reference numerals, and a description thereof will be simplified or omitted.

The platform 117a includes a cache server 130. The cache server 130 stores data to be utilized in the digital dashboard. The cache server 130 may include a plurality of cache servers, and may include, for example, a first database in which recipe information to be used in a processing device for processing a sample is stored, and a second database in which an electron microscope image of the sample is stored. The application server 109 directly or indirectly communicates with the first database and the second database, and processes data acquired from the processing device, the first database, and the second database based on a template used in the digital dashboard.

Although data is also accumulated in the cache server 130 similarly to the database server 106, the cache server 130 deletes past data from the accumulated data. For example, in a method for deleting data, a storage period is determined for each data type, and data in which an accumulation time is longer than the storage period is deleted. In addition, a method for deleting data can be appropriately set according to a user request.

Although the case in which the cache server 130 is used is described, the present disclosure is not limited to this case. Other configurations may be adopted as long as the data utilized in the digital dashboard is stored in the cache.

### Functions and Effects

In general, since data related to wafer processing increases every time a time elapses, a sufficient capacity is required for the storage area.

On the other hand, in the second embodiment, since the cache server 130 deletes the past data, it is possible to secure the data necessary for creating the digital dashboard while reducing the storage capacity. When requesting data, reading the data from the cache server 130 is faster than reading the data from a database, and a load is reduced. Therefore, when a digital dashboard and a report are created, it is possible to improve overall performance of the semiconductor device manufacturing system 1a.

Although embodiments of the invention are described above, the invention is not limited to the embodiments described above, and various changes can be made without departing from the gist of the invention.

Aspects that may be contents of the invention will be described below, and the invention is not limited thereto.

### Aspect 1

A terminal connected to a network including at least a first database storing recipe information to be used in a semiconductor manufacturing device configured to process a sample, a second database storing an electron microscope image of the sample, and a server that allows direct or indirect communication with the first database and the second database includes: a processor configured to process a communication protocol with the network; and a user interface (hereinafter, referred to as a “UI”) configured to display information stored in the first database or the second database. A digital dashboard is displayed on the UI, the digital dashboard displaying the recipe information or the electron microscope image in response to a request input from the UI.

### Aspect 2

In the terminal according to Aspect 1, the digital dashboard includes a microscope report including a microscope image or a particle report including foreign matter information.

### Aspect 3

In the terminal according to Aspect 1 or 2, the server has an editing function for creating a report based on display of the digital dashboard.

### Aspect 4

In the terminal according to any one of Aspects 1 to 3, the server includes a VER application for calculating an etch rate.

### Aspect 5

In the terminal according to any one of Aspects 1 to 4, the server has a function of accessing data based on a Run number designated from the UI of the terminal.

### Aspect 6

In the terminal according to any one of Aspects 1 to 5, the server has a function of storing the report, and reading and searching the stored report.

### Aspect 7

In the terminal according to any one of Aspects 1 to 6, the server has a function of storing a report with a document number attached to the report, and searching the stored report using the document number as an ID.

### Aspect 8

In the terminal according to any one of Aspects 1 to 7, the server processes data acquired from the semiconductor manufacturing device, the first database, and the second database based on a template to be used in the digital dashboard.

### Aspect 9

The terminal according to Aspect 1 further includes a memory. The memory stores an application program that is executed by the processor to create the digital dashboard.

### Aspect 10

A semiconductor device manufacturing system includes: a network including at least a semiconductor manufacturing device configured to process a sample, a first database storing recipe information to be used in the semiconductor manufacturing device, a second database storing an electron microscope image of the sample, and a server that allows direct or indirect communication with the first database and the second database; and a terminal connected directly or indirectly to the network and to the server. A digital dashboard is displayed on a user interface provided on the terminal, which displays the recipe information or the electron microscope image in response to a request from the terminal.

### Aspect 11

A display method for displaying a digital dashboard on a user interface (hereinafter, also referred to as a “UI”) in a semiconductor device manufacturing system including a network including at least a semiconductor manufacturing device configured to process a sample, a first database storing recipe information to be used in the semiconductor manufacturing device, a second database storing an electron microscope image of the sample, and a server that allows direct or indirect communication with the first database and the second database, and a terminal including the user interface and connected directly or indirectly to the network and to the server, the method includes: processing data acquired from the semiconductor manufacturing device, the first database, and the second database based on a template to be used in the digital dashboard; and displaying, on the UI, the digital dashboard that displays the recipe information or the electron microscope image in response to a request from the UI of the terminal.

### REFERENCE SIGNS LIST

1, 1a: semiconductor device manufacturing system
101: semiconductor manufacturing device PC
102: semiconductor inspection device PC
103: semiconductor analysis device PC
104: semiconductor analyzer PC
105: relay PC
106: database server
108: gateway PC
109: application server
110: WEB Server
111: GPU Server
113: internet
114: user personal computer
115: user mobile terminal personal computer
116: remote monitor personal computer
117, 117a: platform (network)
118: route setting PC
120: device
121: wafer
122: resist layer
130: cache server
300: microscope image display
400: foreign matter information display

1. A terminal connected to a network including at least a first database storing recipe information to t be used in a semiconductor manufacturing device configured to process a sample, a second database storing an electron microscope image of the sample, and a server that allows direct or indirect communication with the first database and the second database, the terminal comprising:
a processor configured to process a communication protocol with the network; and
a user interface (hereinafter, referred to as a “UI”) configured to display information stored in the first database or the second database, wherein
a digital dashboard is displayed on the UI, the digital dashboard displaying the recipe information or the electron microscope image in response to a request input from the UI.

2. The terminal according to claim 1, wherein
the digital dashboard includes a microscope report including a microscope image or a particle report including foreign matter information.

3. The terminal according to claim 1, wherein
the server has an editing function for creating a report based on display of the digital dashboard.

4. The terminal according to claim 1, wherein
the server includes a VER application for calculating an etch rate.

5. The terminal according to claim 1, wherein
the server has a function of accessing data based on a Run number designated from the UI of the terminal.

6. The terminal according to claim 3, wherein
the server has a function of storing the report, and reading and searching the stored report.

7. The terminal according to claim 6, wherein
the server has a function of storing a report with a document number attached to the report, and searching the stored report using the document number as an ID.

8. The terminal according to claim 1, wherein
the server processes data acquired from the semiconductor manufacturing device, the first database, and the second database based on a template to be used in the digital dashboard.

9. The terminal according to claim 1, further comprising:
a memory, wherein
the memory stores an application program that is executed by the processor to create the digital dashboard.

10. A semiconductor device manufacturing system comprising:
a network including at least a semiconductor manufacturing device configured to process a sample, a first database storing recipe information to be used in the semiconductor manufacturing device, a second database storing an electron microscope image of the sample, and a server that allows direct or indirect communication with the first database and the second database; and
a terminal connected directly or indirectly to the network and to the server, wherein
a digital dashboard is displayed on a user interface provided on the terminal, which displays the recipe information or the electron microscope image in response to a request from the terminal.

11. A display method for displaying a digital dashboard on a user interface (hereinafter, also referred to as a “UI”) in a semiconductor device manufacturing system including
a network including at least a semiconductor manufacturing device configured to process a sample, a first database storing recipe information to be used in the semiconductor manufacturing device, a second database storing an electron microscope image of the sample, and a server that allows direct or indirect communication with the first database and the second database, and
a terminal including the user interface and connected directly or indirectly to the network and to the server,
the method comprising:
processing data acquired from the semiconductor manufacturing device, the first database, and the second database based on a template to be used in the digital dashboard; and
displaying, on the UI, the digital dashboard that displays the recipe information or the electron microscope image in response to a request from the UI of the terminal.
